(19) United States
(12) Patent Application Publication
(10) Pub. No.: US 2009/0246474 A1
(43) Pub. Date: Oct. 1, 2009

(54) ELECTRONIC COMPONENT MOUNTED STRUCTURE AND METHOD OF MANUFACTURING THE SAME

(75) Inventors: Daisuke Sakurai, Osaka (JP); Kazuya Usirokawa, Osaka (JP); Shozo Ochi, Osaka (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/407,369

(22) Filed: Mar. 19, 2009

(30) Foreign Application Priority Data
Mar. 27, 2008 (JP) 2008-082286

(51) Int. Cl. B32B 7/02; C23C 14/22; B32B 3/00

(52) U.S. Cl. 428/172; 428/212; 427/255.6

(57) ABSTRACT

An electronic component mounted structure is constituted by connecting together via a conductive adhesive 2 the electrode terminals 1a of a first electronic component such as a semiconductor element 1 and the electrode terminals 6a (here, projecting electrodes formed thereon) of a second electronic component such as a circuit substrate 6, and filling a molding resin 4 into a gap between the semiconductor element 1 and the circuit substrate 6. The molding resin 4 is composed of a low elasticity layer 3 and a high elasticity layer having higher elasticity than the low elasticity layer, and the low elasticity layer 3 lies adjacent to the whole of the outer surface of the conductive adhesive 2.

### BACKGROUND OF THE INVENTION

1. Field of the Invention

The present invention relates to an electronic component mounted structure and a method of manufacturing the same.

2. Description of the Related Art

In recent years, reduced pitch and more compact surface area have been sought in the electrode terminals of semiconductor elements in order to advance the high-density mounting of the semiconductor elements, such as LSI. One way of doing this is the development of a flip-chip mount in which projecting electrodes (conductive bumps such as solder bumps) are formed on top of the electrode terminals of a semiconductor element, and the semiconductor element is placed face down and pressed and heated onto the connecting terminals of a mounting substrate, becoming connected to the same by means of the projecting electrodes. The projecting electrodes are subject to very strict requirements.

In a flip-chip mount, not only is it necessary to apply a high temperature exceeding 260° C., for example, but it is also necessary to apply a high pressure during the process of forming the projecting electrodes and during the mounting process, and therefore a large mechanical load is placed on the semiconductor element. Furthermore, shorting between adjacent electrode terminals may occur on the mounting substrate adapted for the narrowing of the pitch between the electrode terminals of the semiconductor element, and connection defects may occur due to the stress generated as a result of the difference between the thermal coefficient of expansion of the semiconductor element and that of the mounting substrate.

If a low dielectric constant film (a so-called low-k film or ULK (Ultra Low-k) film, etc.) is used as the insulating film between layers of the semiconductor element to respond to a minute wiring rule and high speed signal processing, then the low dielectric constant film itself is porous and contains a large number of holes of several nanometers in order to reduce the dielectric constant, and therefore it is weak in respect of stress loadings, and may break due to the concentration of stress in the pressure bonding step during mounting, or under operating conditions.

Consequently, there is a strong requirement for the steps of forming the projecting electrodes and mounting the element to be carried out using a low applied pressure, and for the stress loading which occurs after mounting and sealing to be absorbed. In particular, in the case of mobile electronic equipment, such as mobile telephones, laptop computers, PDAs, digital video cameras, and the like, there is a possibility of the equipment receiving an impact due to being dropped, and if the strength of the connections between electrode terminals is not sufficiently reliable, then this can lead to equipment defects. Therefore, very strict requirements apply to such connections.

In response to these requirements, there is a method which forms gold stud bumps on the aluminum electrode terminals of a semiconductor element, and performs connection by transferring cream soldering onto the same (see, for example, Japanese Patent Application Publication No. 5-190599). However, since it is necessary to apply ultrasonic waves and high pressure in the step of forming stud bumps on the aluminum electrode terminals, then there is a possibility of breaking in the fragile interlayer insulating film which is provided directly below the electrode terminals. Moreover, although this connection method allows the semiconductor element to be repaired, a plurality of steps are required in order to form projecting electrodes having a two-stage structure, such as stud bumps, and this leads to increased costs.

Furthermore, there is a structure for a projecting electrode in which a pointed core section having a circular or triangular conical shape is formed by means of a thermocurable conductive adhesive on the electrode terminals of the semiconductor element, and a conductive adhesive is also applied to the outer surfaces of the same (see, for example, Japanese Patent Application Publication No. 11-312711). However, it is not possible to control the amount of spreading of the conductive adhesive after mounting in a semiconductor element having a narrow pitch between electrode terminals, and hence there is a possibility of shorting between the electrodes. Stress is concentrated at the front ends of the projecting electrodes during the pressure bonding step for connecting the semiconductor element, and may possibly cause damage to the semiconductor element or the fragile insulating film between layers.

There is also a method in which stress absorbing balls consisting of a polymer sphere having conductive material formed on the surface thereof are disposed between the electrode terminals of a semiconductor element and the connection terminals of a wiring substrate, and the conductive material is caused to diffuse and become bonded to the electrode terminals and the connection terminals, whereby the stress generated during the pressure bonding and heating steps is absorbed by the stress absorbing balls, thus reducing connection defects, in addition to which the electrical resistance is reduced by the diffusion bonding (see, for example, Japanese Patent Application Publication No. 5-21519). However, the smaller the size of the stress absorbing balls, the higher the manufacturing costs, and since these very small stress absorbing balls are disposed on top of the electrode terminals and used as bump electrodes, then it is difficult to dispose the balls having a high aspect ratio in accordance with this miniaturization, and hence high-density mounting is difficult to achieve.

There is also a method in which projecting electrodes formed on aluminum electrode terminals of a semiconductor wafer are each constituted by a projecting electrode core made of a projection-shaped insulating body having elastic properties, and a metal film which is formed on the surface thereof by vapor deposition, sputtering, or the like; and the elastic deformation of the projecting electrode core is used to restrict any reduction in production yield during connection due to the effects of height variations in the projecting electrodes of the semiconductor elements cut out from the semiconductor wafer, and the flatness of a wiring substrate to which the elements are connected (see, for example, Japanese Patent Application Publication No. 3-62927). However, even with this method, in order to form projecting electrodes, complicated processes are required in the preparation and vapor deposition of the elastic projecting electrode cores described above, and this leads to increased costs. Furthermore, a uniform high pressure needs to be applied during the mounting process in order to obtain an electrical connection by metal to metal bonding between the surface metal film of the projecting electrodes and the connection terminals of the semiconductor element and the wiring substrate, and consequently the problem of breaking of the semiconductor element, and especially the insulating film between layers, still persists.

### SUMMARY OF THE INVENTION

The present invention was devised in view of the aforementioned problems, an object thereof being to provide an electronic component mounted structure having a simple structure in which electronic components can be connected by means of a low applied pressure, as well as being able to ensure high reliability of the connections.

In order to achieve the aforementioned object, the present invention provides an electronic component mounted structure in which an electrode of a first electrode component and an electrode of a second electrode component are connected via a conductive adhesive, and a molding resin is filled into a gap between the first and second electronic components, wherein the molding resin is composed of a low elasticity layer and a high elasticity layer having higher elasticity than the low elasticity layer, and the low elasticity layer lies adjacent to the whole of the outer surface of the conductive adhesive.

Furthermore, according to the present invention, the electronic component mounted structure as described above is manufactured by carrying out: a first step of supplying a conductive adhesive in the form of a paste to one or both of an electrode of a first electronic component and an electrode of a second electronic component; a second step of placing the electrodes of the first and the second electronic components so as to oppose each other via the conductive adhesive; a third step of drying or curing the conductive adhesive; a fourth step of filling a molding resin into a gap between the first and the second electronic components; a fifth step of forming an intermediate layer adjacent to the connecting section created by the conductive adhesive; and a sixth step of forming a low elasticity layer constituted by the intermediate layer and a high elasticity layer having higher elasticity than the low elasticity layer, by curing the molding resin.

According to the respective compositions described above, high pressure is not required because a conductive adhesive is used to connect the first and second electronic components. Furthermore, the stress generated in the pressure bonding and heating steps during the process of curing the molding resin, and the pressure and thermal stress applied under operating conditions after mounting are absorbed by the low elasticity layer (intermediate layer) and therefore concentration of stress at the electrode surfaces of the first and/or second electrode components can be prevented. Therefore, high reliability of the connections can be ensured while adopting a simple structure. One of the first and second electronic components may be a circuit substrate.

The elasticity of the conductive adhesive is lower than the elasticity of the molding resin. Accordingly, the pressure and thermal stress applied during mounting (connection), and under operating conditions after mounting, can be absorbed by the low elasticity layer in the conductive adhesive and molding resin.

This low elasticity layer is formed by the resin component of the conductive adhesive fusing into the resin component of the molding resin, and preferably, the volumetric density of the non-conductive filler in the low elasticity layer is lower than the volumetric density of the non-conductive filler in the high elasticity layer. Desirably, the conductive resin includes a resin that has been flexibilized.

A projecting electrode may be formed on the electrode of the second electronic component. For this purpose, before the first step, a step of forming a projecting electrode on the electrode of the second electronic component is carried out, and in the first step, the conductive adhesive is supplied to either the projecting electrode or the electrode of the first electronic component. If a connection structure of high aspect is adopted in this way, then the shearing stress acting on the connected electrode surfaces is reduced, and therefore even better connection reliability can be ensured.

The intermediate layer forming a low elasticity layer can be formed by restricting the curing rate of the molding resin and causing the resin component of the conductive adhesive to become fused into the resin component of the molding resin. By this means, it is possible to manufacture a low elasticity layer easily, without having to apply pressure.

The intermediate layer which forms the low elasticity layer can be formed by vapor deposition of a high polymer material having low elasticity. By this means, it is possible to manufacture a uniform layer of low elasticity without using a complicated process.

### BRIEF DESCRIPTION OF THE DRAWINGS

FIG. 1 is a cross-sectional diagram showing a conceptual view of the structure of an electronic component mounted structure according to a first embodiment of the present invention;

FIGS. 2A to 2E are cross-sectional diagrams illustrating a method of manufacturing the electronic component mounted structure in FIG. 1;

FIG. 3 is a cross-sectional diagram showing a conceptual view of the structure of an electronic component mounted structure according to a second embodiment of the present invention;

FIG. 4 is a cross-sectional diagram showing a conceptual view of the structure of an electronic component mounted structure according to a third embodiment of the present invention; and

FIGS. 5A to 5E are cross-sectional diagrams illustrating a method of manufacturing the electronic component mounted structure in FIG. 4.

### DESCRIPTION OF THE PREFERRED EMBODIMENTS

Below, embodiments of the present invention are described with reference to the drawings.

### First Embodiment

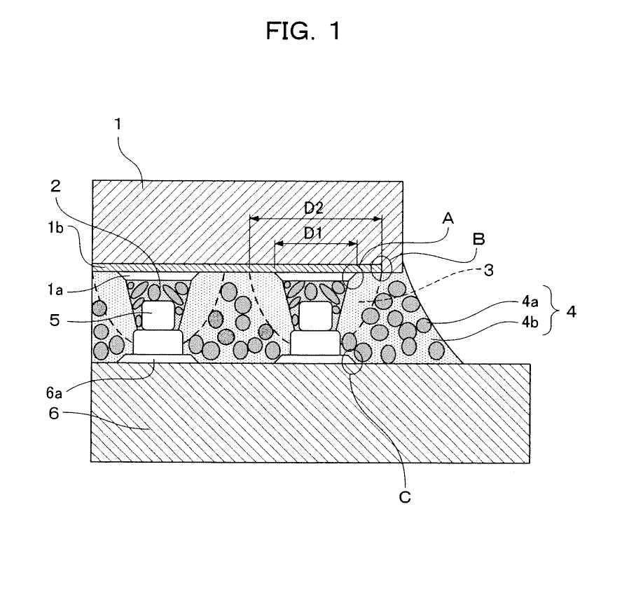

In the electronic component mounted structure shown in FIG. 1, a multi-layer wiring layer 1b consisting of a fine wiring layer and a fragile low-dielectric-constant insulating film (for example, a Low-k layer or Ultra low-k layer) is provided on the principal surface of a semiconductor element 1 which forms an electronic component, and a plurality of electrode terminals 1a are provided in an area arrangement on the uppermost surface thereof. This principal surface is called the “electrode surface” below.

A circuit substrate 6 on which the semiconductor element 1 is mounted (for example, a glass epoxy multi-layer substrate, an aramid multi-layer substrate, a silicon substrate) has electrode terminals 6a in an arrangement opposing the electrode terminals 1a of the semiconductor element 1, and metal projecting electrodes 5 (so-called “stud bumps”) are formed on each of the electrode terminals 6a. The electrode terminals 1a and 6a are made of gold, aluminum, nickel or copper, and the projecting electrodes 5 are made of gold or copper.

The electrode terminals 1a of the semiconductor element 1 and the projecting electrodes 5 of the circuit substrate 6 are bonded together electrically and mechanically by means of a conductive adhesive 2. Molding resin 4 is filled into the gap between the electrode surface of the semiconductor element 1 and the circuit substrate 6, apart from the connecting sections between the electrode terminals 1a and the projecting electrodes 5. The portion of the molding resin 4 which covers at least the whole of the outer surface of the conductive adhesive 2 is called the “low elasticity layer 3”. The molding resin 4 other than the low elasticity layer 3 has higher elasticity than the low elasticity layer 3.

In order to obtain an electrical connection, the conductive adhesive 2 consists of at least a conductive filler and a resin component, and here, it must have low elasticity in order to alleviate stress in the connecting sections of the semiconductor element 1; for example, a material having elasticity of 1×10⁸ to 4×10⁹ Pa is used. For the conductive filler, it is possible to use, for instance, at least one of silver, gold, a silver/palladium alloy, copper, gold-plated resin balls, or solder particles. In order to achieve low elasticity, for example, a resin of low elasticity is used, or a resin of high elasticity is taken and imparted with flexible properties. Possible examples of a low elasticity resin may include, for instance, a rubber resin, such as a silicone resin, butadiene rubber, silicone rubber, urethane, or the like. Possible examples of a resin which is used after being flexibilized are: an acrylic resin, a polyester resin, an epoxy resin, a phenol resin, a polyimide resin, and the like. Known methods for flexibilizing a resin are either by polymerizing and modifying silicone, or the like, and by increasing the content of thermoplastic component.

The molding resin 4 includes at least an inorganic filler 4a and a resin component 4b, and has elasticity of 3×10⁹ to 4×10¹⁰ Pa, for example. The inorganic filler is one of silica or alumina, for example. The resin composition may be, for example, one of epoxy, acrylic, polyester, or urethane. The low elasticity layer 3 has, for example, elasticity of 1×10⁸ to 4×10⁹ Pa.

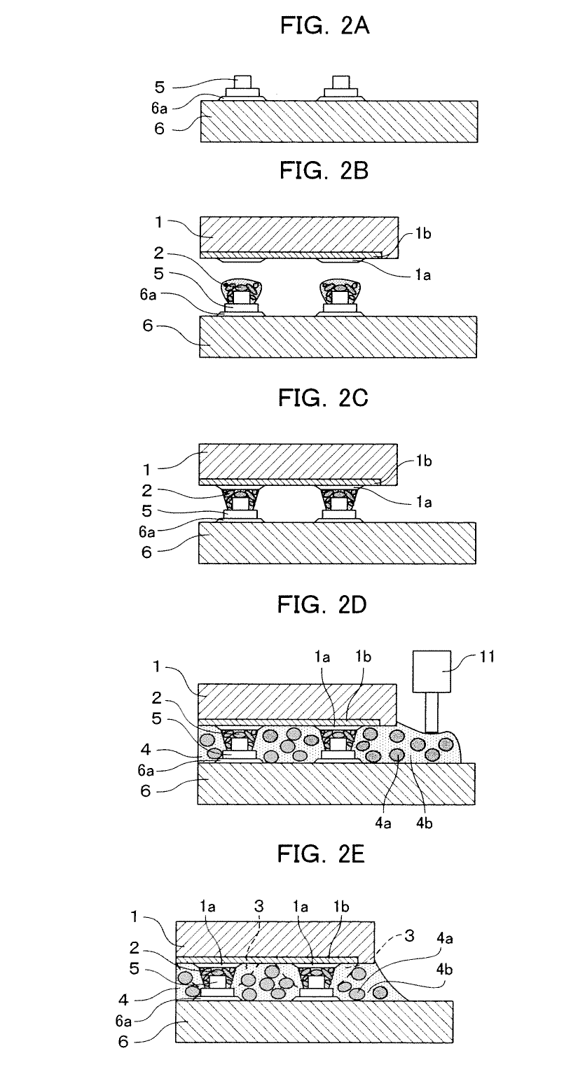

The method of manufacturing the electronic component mounted structure described above will now be explained with reference to FIGS. 2A to 2E.

As shown in FIG. 2A, the projecting electrodes 5 are formed on the electrode terminals 6a of the circuit substrate 6 by wire bonding (plating, inkjet method, or the like), and as shown in FIG. 2B, a conductive adhesive 2 is supplied onto the projecting electrodes 5 by a transfer method (screen printing, a dispenser, or the like, may be used). As shown in FIG. 2C, the semiconductor element 1 is mounted on the circuit substrate 6 by facing the electrode terminals 1a toward the substrate and aligning them in position with the electrode terminals 6a, and the conductive adhesive 2 is dried or cured in a heating oven, or the like.

As shown in FIG. 2D, a liquid molding resin 4 is supplied and filled into the gaps between the semiconductor element 1 and the circuit substrate 6, by using a dispenser 11, or the like. The semiconductor element 1 and the circuit substrate 6 which have been joined together in this way are introduced into a heating oven, or the like, and as shown in FIG. 2E, an intermediate layer consisting of a low elasticity layer 3 which surrounds the conductive adhesive 2 is formed, whereupon the temperature is raised further thereby curing the molding resin 4 including the intermediate layer.

Although the mechanism of forming the low elasticity layer 3 is not clear, it is thought to be as follows. The conductive adhesive 2 is cured or dried until achieving a solid state (for example, curing temperature: 120 to 180° C.; curing time: 5 to 120 minutes; pressure: atmospheric pressure) and when the liquid molding resin 4 is injected about the perimeter of the solidified conductive adhesive 2, then the resin component in the conductive adhesive 2 starts to fuse into the resin component of the molding resin 4.

When the structure is transferred to the resin curing step in this state, the molding resin 4 in liquid form is heated to a high temperature of 120 to 180° C., for example, and therefore the melting of the resin component in the conductive adhesive 2 is accelerated and a new resin layer (intermediate layer) is formed in which the resin components of the molding resin 4 and the conductive adhesive 2 are fused into each other. After reaching a prescribed temperature, the main component and the curing agent in the molding resin 4 start a cross-linking reaction and a low elasticity layer 3 which is suitable as the intermediate layer described above is formed, together with the rest of the molding resin 4 (cured resin).

In this case, the inorganic filler 4a which is present in the region where the intermediate layer is formed becomes concentrated in the molding resin 4 on the outer circumferential side of the intermediate layer due to convection during the formation of the intermediate layer and weight of the inorganic filler, and therefore the inorganic filler 4a in the low elasticity layer 3 thus formed has a low volumetric density and hence low elasticity is achieved. If the inorganic filler 4a is made of very fine particles, then its weight is low and due to the effect of buoyancy, it is difficult, even with convection, to concentrate on the outer circumferential side of the intermixed layer, in other words, on the outside of the low elasticity layer 3, and therefore a filler particle size of 1.0 μm or greater is desirable, and 3.0 μm or greater is more desirable.

In order to form the low elasticity layer 3, the dissolution of the resin component in the conductive adhesive 2 needs to start before the curing reaction of the molding resin 4 has been completed, so that an intermediate layer is formed. The way to achieve this is to restrict the curing speed of the molding resin 4, for instance, by lengthening the gelling time through suitable material design, slowing the rate of temperature rise, using a multiple-step profile, and the like.

The description returns now to FIG. 1. In the electronic component mounted structure obtained after the resin has been cured, a low elasticity layer 3 is formed so as to cover at least the whole of the outer surface of the conductive adhesive 2, namely, to cover from a portion of the projecting electrode 5 until the electrode surface of the semiconductor element 1 surrounding the electrode terminal 1a, as shown in FIG. 1, and the outer sides of the respective portions of the low elasticity layer 3 are thus filled in with molding resin 4 having higher elasticity than the low elasticity layer 3. The spreading surface area of the low elasticity layer 3 on the semiconductor element 1 (indicated by diameter D2) is greater than the spreading surface area of the conductive adhesive 2 (indicated by diameter D1). For example, if the pitch of the electrode terminals 1a and 6a is 180 μm, then although the value depends on the type of conductive adhesive 2 or molding resin 4, or the like, the spreading rate D1 of the conductive adhesive 2 is a diameter of 70 to 90 μm, and the spreading rate D2 of the low elasticity layer 3 is a diameter of 90 to 120 μm. This structure and these dimensions were measured using an electron microscope with a measurement function, after exposing the junctions of the semiconductor element 1 by means of a cutting method, such as sectional polishing or FIB.

In general, when an electronic component mounted structure is used under conditions of severe temperature change, breakage is liable to occur due to the large difference in elasticity between the semiconductor element 1 and the molding resin 4. In particular, if the elasticity of the connecting section is higher than that of the molding resin 4, then stress concentrates in the connection terminal section A at the corner and there is a possibility that the fragile insulating film (one layer inside the multiple-layer wiring layer 1b) may fracture, or the insulating layer may progressively become detached, starting from A.

For example, if a molding resin 4 (3×10⁹ to 4×10¹⁰ Pa) and a conductive adhesive 2 (1×10⁸ to 4×10⁹ Pa) are used in the case of a circuit substrate 6 (3×10⁹ Pa; elasticity, same applies below), a semiconductor element 1 (1.7×10¹¹ Pa), and a projecting electrode 5 (8×10¹⁰ Pa), then there is a large difference in elasticity between the semiconductor element 1 and the molding resin 4 in the connecting section on the semiconductor element 1 side.

However, in the structure according to the present embodiment, a layer of low elasticity similar to that of the conductive adhesive 2, namely the low elasticity layer 3 (1×10⁸ to 4×10⁹ Pa), is formed, and the point of maximum stress loading on the semiconductor element 1 side is shifted away from the connection terminal section A towards B, and hence the load applied to the connection terminal section A can be reduced. On the other hand, since the projecting electrode 5 has high elasticity in comparison with the conductive adhesive 2 and the low elasticity layer 3, then the stress concentrated in the connection terminal section C on the circuit substrate 6 is higher than the stress applied to the terminal section B in the low elasticity layer, but since there is no fragile insulating film directly below C, then fracturing or detachment does not occur on the circuit substrate 6 and a stable connection is obtained.

In this way, by means of the structure according to the present embodiment, not only is it possible to connect a semiconductor element 1 having narrow pitch between electrode terminals 1a and a fragile insulating film, by means of a low pressure, but it is also possible to achieve a stable connection in terms of reliability during the pressurization and heating steps, and after mounting. Furthermore, the method and materials employed are simple and inexpensive. Moreover, shorting does not occur and hence compatibility with narrow pitch is achieved. On the other hand, by making the conductive adhesive 2 have low elasticity and increasing the spreading diameter D1, it is possible to prevent the concentration of stress, but increasing the spreading diameter D1 gives rise to shorting and is not compatible with narrow pitch.

The elasticity of the conductive adhesive 2, low elasticity layer 3 and molding resin 4 described above was calculated by cutting a mounted body and polishing the sectioned face thereof in such a manner that the connecting section could be observed and then carrying out a load/unload test using a dynamic ultra-micro hardness tester to find the stress-strain curve.

The elasticity is not the only index which can be used in choosing the conductive adhesive 2 and the molding resin 4 which form the low elasticity layer 3, and it is also possible to choose on the basis of the hardness, for instance. The elasticity and hardness have the relationship described below. If the same pressure is applied to different materials, then the pushing depth is greater, the lower the elasticity of the material, while the dynamic hardness is inversely proportional to the square of the pushing depth. Consequently, the dynamic hardness becomes smaller, then lower the elasticity. The dynamic hardnesses of the respective materials described above were 80, 20, 10 and 5, for the projection electrode 5, the molding resin 4, the conductive adhesive 2 and the low elasticity layer 3, and this order of magnitudes also reflects their respective elasticities.

An electronic component mounted structure such as that described above was test manufactured, and the conductive adhesive 2 and the molding resin 4 capable of forming a low elasticity layer 3 were investigated. The circuit substrate 6 used was a four-layer multi-layer substrate (made of aramid) in which electrode terminals 6a of diameter 70 to 100 μm having an outermost surface made of gold were formed in an area arrangement at a pitch of 225 μm on the surface of the substrate. The semiconductor element 1 had a shape corresponding to the circuit substrate 6 and electrodes 1a of diameter 70 to 100 μm having an outermost surface made of gold were formed on the semiconductor element 1.

The conductive adhesive 2 used was a silver paste having a resin component consisting of a flexibilized epoxy resin (not containing a curing agent) diluted in a solvent (for example, butyl carbitol acetate, ethanol, or the like) to reduce the viscosity, and after connecting the circuit substrate with the semiconductor element, the adhesive was dried and solidified for one hour at 120° C. Molding resins 4 of four types (A, B, C, D) were prepared and respectively injected into the gaps between the circuit substrate 6 and the semiconductor element 1 and left for 10 minutes, before being cured in a batch oven at a curing rate of 30 to 100° C./min and controlled to a maximum temperature of 150 to 180° C.

After the molding resin 4 had been cured, the presence or absence of a low elasticity layer 3 having a low density content of the inorganic filler was evaluated by observing the cross-section. More specifically, the presence or absence of a low elasticity layer 3 was judged based on a value obtained by subtracting D2 from D1, where D1 is the spreading diameter of the conductive adhesive 2 on the electrode surface of the semiconductor element 1, and D2 is the spreading diameter of the low elasticity layer 3. The results are shown in Table 1.

TABLE 1

| Molding | | | | |
|---|---|---|---|---|
| resin | A | B | C | D |
| Base resin | Special | Bisphenol | Bisphenol | Bisphenol |
| | epoxy | A | A | F |
| | | | Bisphenol | |
| | | | F | |
| Curing | Acid | Acid | Acid | Amino |
| agent | anhydride | anhydride | anhydride | |
| Gelling | 100 | 120 | 50 | 10 |
| time | | | | |
| (seconds) | | | | |
| Stress | 30 to 60 | 30 to 60 | 30 to 60 | No layer |
| alleviating | | | | of 1 μm or |
| layer (D2- | | | | above |
| D1) μm | | | | detected |

In the case of the molding resins A, B, C which have a long gelling time (50 to 120 s), a low elasticity layer of 30 to 60 μm was formed. In the molding resin D having a short gelling time (10 s), it was not possible to confirm the formation of a low elasticity layer of 1 μm or greater. This is thought to be because the curing reaction had started before fusion could begin.

Although expected electrical operation was confirmed initially in all of the test manufactured electronic component mounted bodies, in an environmental reliability test, breaking of the fragile Low-k layer was observed in the electronic component mounted structure manufactured using the molding resin D. In the electronic component mounted bodies manufactured using the molding resins A, B and C, no breakage was observed.

### Second Embodiment

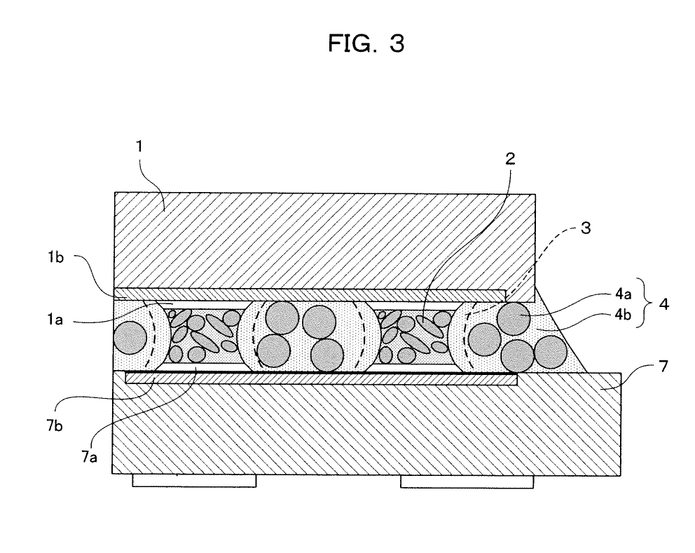

In the electronic component mounted structure shown in FIG. 3, similarly to the first embodiment, the semiconductor element 1 (hereinafter, called the “first semiconductor element 1”) comprises a multi-layer wiring layer 1b consisting of a fine wiring layer and a fragile low-dielectric-constant insulating film (for example, a Low-k layer or Ultra low-k layer) provided on the electrode surface, and a plurality of electrode terminals 1a are provided in an area arrangement on the uppermost surface thereof. A second semiconductor element 7 which is disposed so as to oppose the first semiconductor element 1 has electrode terminals 7a in an arrangement opposing the electrode terminals 1a, and a porous low dielectric constant insulating film 7b underneath the electrode terminals 7a.

The first electrode terminals 1a of the first semiconductor element 1 and the electrode terminals 7a of the second semiconductor element 7 are connected electrically and mechanically by means of a conductive adhesive 2. A low elasticity layer 3 is formed about the periphery of each connecting section between an electrode terminal 1a and an electrode terminal 7a, and the low elasticity layer 3 covers the periphery of the conductive adhesive 2, the electrode surface about the periphery of the electrode terminal 1a and the electrode surface about the periphery of the electrode terminal 7a. Apart from this, a molding resin 4 is filled into the gap between the first semiconductor element 1 and the second semiconductor element 7.

The conductive adhesive 2 and the low elasticity layer 3 have low elasticity compared to the molding resin 4 after curing. For example, whereas the molding resin 4 has elasticity of 3×10⁹ to 4×10¹⁰ Pa, the conductive adhesive 2 and the low elasticity layer 3 have elasticity of 1×10⁸ to 4×10⁹ Pa and a thickness of 4 to 20 μm. Apart from this, the embodiment is the same as the first embodiment.

In the case of this electronic component mounted structure also, since the connecting section between the electrode terminals 1a and 7a is constituted by the conductive adhesive 2 and the low elasticity layer 3 which have low elasticity, and since the low elasticity layer 3 also covers the electrode surface about the periphery of the electrode terminals 1a and 7a, stress does not concentrate in the vicinity of the electrode terminals 1a and 7a, and the progression of cracks in the fragile insulating film can be prevented.

When manufacturing an electronic component mounted structure having the structure described above, firstly, the conductive adhesive 2 is supplied onto the electrode terminal 7a of the second semiconductor element 7 and the first semiconductor element 1 is mounted on the second semiconductor element 7 by aligning the electrode terminal 1a with the electrode terminal 7a. The conductive adhesive 2 is dried and the molding resin 4 is supplied and filled into the gap between the first semiconductor element 1 and the second semiconductor element 2. Thereupon, the first semiconductor element 1 and the second semiconductor element 7 which have been joined together are introduced into a heating oven, or the like, a low elasticity layer 3 is formed so as to surround the conductive adhesive 2, and the low elasticity layer 3 and the molding resin 4 are cured.

According to the method of present embodiment, it is possible to produce, simply and inexpensively, and using a low pressure, an electronic component mounted structure in which semiconductor elements having narrow pitch and fragile insulating films are connected together. A conductive adhesive may previously be supplied to and cured on the electrode terminals 1a of the first semiconductor element 1 which is mounted. By this means, it is possible to form a junction section of high aspect ratio, and therefore the stress alleviating effect is enhanced.

### Third Embodiment

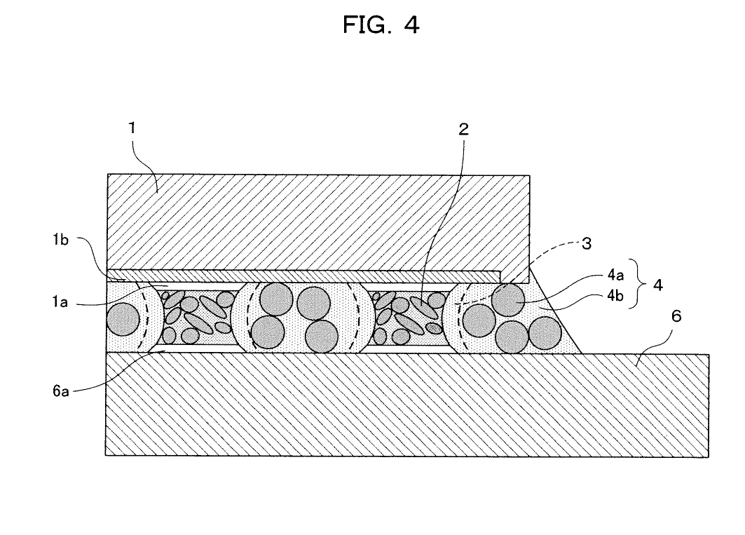

The electronic component mounted structure shown in FIG. 4 is the same as that in the first embodiment, with the exception that projecting electrodes are not formed on the electrode terminals 6a of the circuit substrate 6. The electrode terminals 1a of the semiconductor element 1 and the electrode terminals 6a of the circuit substrate 6 are bonded together electrically and mechanically by means of a conductive adhesive 2.

A low elasticity layer 3 is formed about the periphery of each connecting section between an electrode terminal 1a and an electrode terminal 6a, and the low elasticity layer 3 covers the periphery of the conductive adhesive 2, the electrode surface about the periphery of the electrode terminal 1a and the electrode surface about the periphery of the electrode terminal 6a. Apart from this, a molding resin 4 is filled into the gap between the semiconductor element 1 and the circuit substrate 6. The materials of the conductive adhesive 2 and the molding resin 4 are similar to those of the first embodiment.

In the case of this electronic component mounted structure also, since the connecting section between the electrode terminals 1a and 6a is constituted by the conductive adhesive 2 and the low elasticity layer 3 which have low elasticity, and since the low elasticity layer 3 also covers the electrode surface about the periphery of the electrode terminals 1a and 6a, then stress does not concentrate in the vicinity of the electrode terminals 1a and 6a, and the progression of cracks in the fragile insulating film can be prevented.

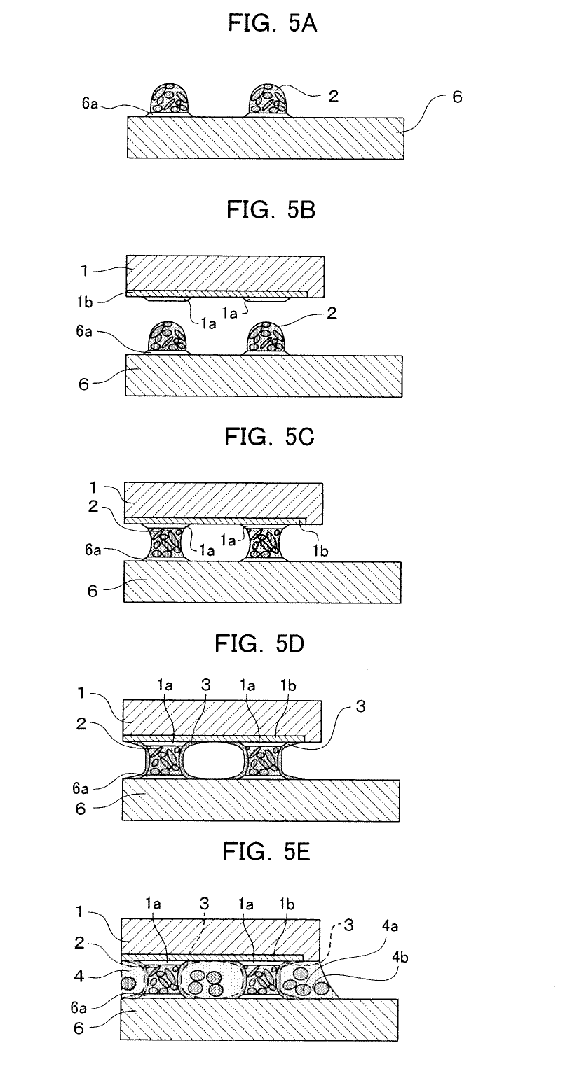

A method of manufacturing the electronic component mounted structure having the structure described above will now be described with reference to FIGS. 5A and 5B.

As shown in FIG. 5A, a conductive adhesive 5 is supplied onto the electrode terminal 6a of the circuit substrate 6. As shown in FIG. 5B, the semiconductor element 1 is aligned in position with the circuit substrate 6, and as shown in FIG. 5C, is mounted thereon and the conductive adhesive 2 is dried.

The semiconductor element 1 and the circuit substrate 6 which have been joined together are introduced into a vacuum oven, and the low elasticity layer 3 shown in FIG. 5D is formed by vapor deposition. In this case, the circuit substrate 6 is installed in a jig in an erect position so as to be perpendicular to the target electrode, and a high polymer material of low elasticity, such as polyimide or polyparaxylene, is sputtered in an inert gas atmosphere, whereupon the circuit substrate 6 is turned through 90 degrees, these operations being repeated until sputtering has been carried out a total of four times. By adopting this method, it is possible to form a low elasticity layer 3 by vapor deposition, reliably, about the perimeter of the connecting section (outermost joint section) in the corner portion of the semiconductor element 1.

Thereupon, as shown in FIG. 5E, a molding resin 4 is injected into the gap between the semiconductor element 1 and the circuit substrate 6 and the molding resin 4 is cured using a curing oven, or the like.

According to the method of the present embodiment, it is possible to form a low elasticity layer 3 regardless of the material of the molding resin 4. Similarly to the first and second embodiments, it is possible to manufacture, simply and inexpensively, and using a low pressure, an electronic component mounted structure in which semiconductor elements having narrow pitch and fragile insulating films are mounted.

After curing, the molding resin 4 has elasticity of 3×10⁹ to 4×10¹⁰ Pa, for example. The conductive adhesive 2 and the low elasticity layer 3 have lower elasticity than the molding resin 4, for example, elasticity of 1×10⁸ to 4×10¹⁰ Pa and a thickness of 4 to 20 μm. The constituent components of the low elasticity layer 3 can be analyzed by sectioning the electronic component mounted structure, polishing the sectioned faces, and then using microscopic Raman scattering or FT-IR. Moreover, the hardness or elasticity can be measured by abutting the probe of a micro hardness tester against the exposed sectioned face.

In the embodiments described above, a semiconductor element and a circuit substrate were given as examples of electronic components, but the electronic components are not limited to these. Similar beneficial effects are obtained when using fragile passive components, such as capacitors, coils, resistances, or the like, or a substrate on which an electronic component has already been mounted.

As described above, according to the present invention, high pressure is not required because a conductive adhesive is used to connect the first and second electronic components. Furthermore, since there is a low elasticity layer, then the stress generated in the pressure bonding and heating steps during the process of curing the molding resin, and the pressure and thermal stress applied under operating conditions after mounting, are absorbed by this low elasticity layer and therefore concentration of stress at the electrode surfaces of the first and/or second electrode components can be prevented. As a result, it is possible to achieve narrow pitch connections, as well as being able to prevent breakdown and ensure high connection reliability when the electronic component is a fragile semiconductor element. Low costs and high productivity can also be achieved.

Therefore, the present invention is especially valuable in the field of mounting elements such as semiconductor elements of reduced thickness, and semiconductor elements having inter-layer insulating films made of a low-k material or ULK material, or the like, which perform high-speed operation.

What is claimed is:

1. An electronic component mounted structure in which an electrode of a first electrode component and an electrode of a second electrode component are connected via a conductive adhesive, and a molding resin is filled into a gap between the first and second electronic components,
wherein the molding resin comprises a low elasticity layer and a high elasticity layer having higher elasticity than the low elasticity layer, and the low elasticity layer lies adjacent to the whole of the outer surface of the conductive adhesive.

2. The electronic component mounted structure according to claim 1, wherein the elasticity of the conductive adhesive is lower than the elasticity of the molding resin.

3. The electronic component mounted structure according to claim 1, wherein the low elasticity layer is formed by the resin component of the conductive adhesive and the resin component of the molding resin fusing into each other, and the volumetric density of non-conductive filler in the low elasticity layer is lower than the volumetric density of non-conductive filler in the high elasticity layer.

4. The electronic component mounted structure according to claim 1, wherein the conductive adhesive includes a resin that has been flexibilized.

5. The electronic component mounted structure according to claim 1, wherein a projecting electrode is formed on the electrode of the second electronic component.

6. A method of manufacturing an electronic component mounted structure comprising a first electronic component and a second electronic component, the method comprising:
a first step of supplying a conductive adhesive in the form of a paste to one or both of an electrode of a first electronic component and an electrode of a second electronic component;
a second step of placing the electrodes of the first and the second electronic components so as to oppose each other via the conductive adhesive;
a third step of drying or curing the conductive adhesive;
a fourth step of filling a molding resin into a gap between the first and the second electronic components;
a fifth step of forming an intermediate layer adjacent to the connecting section created by the conductive adhesive; and
a sixth step of forming a low elasticity layer constituted by the intermediate layer and a high elasticity layer having higher elasticity than the low elasticity layer, by curing the molding resin.

7. The method of manufacturing an electronic component mounted structure according to claim 6, further comprising, before the first step, a step of forming a projecting electrode on the electrode of the second electronic component, wherein in the first step, the conductive adhesive is supplied to the projecting electrode or the electrode of the first electronic component.

8. The method of manufacturing an electronic component mounted structure according to claim 6, wherein the intermediate layer is formed by the resin component of the conductive adhesive and the resin component of the molding resin being caused to fuse into each other by restricting the curing rate of the molding resin.

9. The method of manufacturing an electronic component mounted structure according to claim 6, wherein the intermediate layer is formed by vapor deposition of a polymer material of low elasticity.
